(19) United States
(12) Patent Application Publication
(10) Pub. No.: US 2025/0212302 A1
(43) Pub. Date: Jun. 26, 2025

(54) GENERAL PURPOSE INPUT/OUTPUT (GPIO) FOR ENHANCED CHIP SAFETY

(71) Applicant: Chengdu Monolithic Power Systems Co., Ltd., Chengdu (CN)

(72) Inventor: Yong Zhou, Sichuan (CN)

(21) Appl. No.: 19/001,197

(22) Filed: Dec. 24, 2024

(30) Foreign Application Priority Data
Dec. 26, 2023 (CN) 202311816172.1

(51) Int. Cl. H05B 45/30; H03K 17/687

(52) U.S. Cl. CPC H05B 45/30; H03K 17/6872

(57) ABSTRACT

This disclosure relates to a GPIO circuit having an output circuit. The output circuit includes a first NMOS transistor connected between a GPIO pin and a reference ground, and a first PMOS transistor and a second PMOS transistor coupled in series between an operating voltage output terminal and the GPIO pin. The proposed GPIO circuit is capable of effectively isolating the operating voltage output terminal from the GPIO pin. By adding an LED drive circuit and/or a high-voltage pull-up circuit to the GPIO circuit, the GPIO circuit can flexibly operate in various modes according to application needs.

### CROSS-REFERENCE TO RELATED APPLICATIONS

This application claims the benefit of CN application Ser. No. 202311816172.1 filed on Dec. 26, 2023 and incorporated herein by reference.

### TECHNICAL FIELD

The present invention relates to general purpose input/output circuit.

### BACKGROUND OF THE INVENTION

A general purpose input/output (GPIO) pin is commonly used in a chip which can be programmed to act as either an input or an output. Within the chip, there is a GPIO circuit corresponding to each GPIO pin. The GPIO circuit typically includes both input and output circuits. By controlling the input circuit, the GPIO can be configured to operate in various modes, such as floating input mode, pull-up input mode, and others. Meanwhile, by controlling the output circuit, it can be configured to operate in various modes, such as push-pull output mode and open-drain output mode, among others.

Typically, the output circuit includes a P-type Metal-Oxide-Semiconductor Field-Effect (PMOS) transistor and an N-type Metal-Oxide-Semiconductor Field-Effect (NMOS) transistor, which are connected in series between an operating voltage output terminal and a reference ground. When the GPIO circuit operates in the push-pull output mode, a control circuit of the GPIO circuit drives the PMOS transistor to be turned ON while the NMOS transistor to be turned OFF to pull an output voltage of the GPIO pin up to the same potential as the operating voltage output terminal, or drives the PMOS transistor to be turned OFF while the NMOS transistor to be turned ON to pull the output voltage of the GPIO pin down to the same potential as the reference ground.

However, due to the presence of body diodes of these transistors, when there are multiple selectable power supply voltages within the chip or when the voltage of peripheral devices changes, the operation of turning OFF the PMOS transistor may cause backflow, and in severe cases, it may lead to chip malfunction and damage.

### SUMMARY OF THE INVENTION

Embodiments of this invention relates to a general input/output (GPIO) circuit having an output circuit. The output circuit has a first n-type metal-oxide-semiconductor field-effect (NMOS) transistor which is coupled between a GPIO pin and a reference ground, a first p-type metal-oxide-semiconductor field-effect (PMOS) transistor and a second PMOS transistor which are coupled in series between an operating voltage output terminal and the GPIO pin. The first NMOS transistor includes a source coupled to the reference ground, a drain coupled to the GPIO pin and a gate. The first PMOS transistor includes a drain coupled to the operating voltage output terminal, a gate and a source. The second PMOS transistor includes a drain coupled to the GPIO pin, a gate and a source.

### BRIEF DESCRIPTION OF DRAWINGS

For a better understanding of the invention, embodiments of the invention will be described in accordance with the following drawings, which are used for illustrative purpose only. The drawings illustrate only some of the features in an embodiment. It should be understood that the drawings are not necessarily to scale. Like elements are provided with like reference numerals in different appended drawings.

FIG. 1 is a schematic diagram of a GPIO circuit 100 according to an embodiment of the present disclosure.

FIG. 2 is a schematic diagram of a GPIO circuit 200 according to an embodiment of the present disclosure.

FIG. 3 is a schematic diagram of an exemplary pull-up circuit 300 in accordance with an example embodiment of the present disclosure.

FIG. 4 is a schematic diagram of a GPIO circuit 400 according to an embodiment of the present disclosure.

FIG. 5 is a schematic diagram of an exemplary voltage selection circuit 500 in accordance with an example embodiment of the present disclosure.

FIG. 6 is a schematic diagram of a multifunctional GPIO circuit 600 according to an embodiment of the present disclosure.

FIG. 7 is a schematic diagram of another multifunctional GPIO circuit 700 according to an embodiment of the present disclosure.

### DETAILED DESCRIPTION OF THE INVENTION

Detailed description of the embodiments is provided merely to give examples and not intended to be limiting. Plenty of details are provided to assist the reader in gaining a comprehensive understanding of the present invention. However, many other ways of implementing the disclosure of the present application described herein will be apparent. Description of materials and methods that are known in the art may not be addressed in the present application for simplicity.

Throughout the specification and claims, the phrases “in one embodiment”, “in some embodiments”, “in one implementation”, and “in some implementations” as used includes both combinations and sub-combinations of various features described herein as well as variations and modifications thereof. These phrases used herein do not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

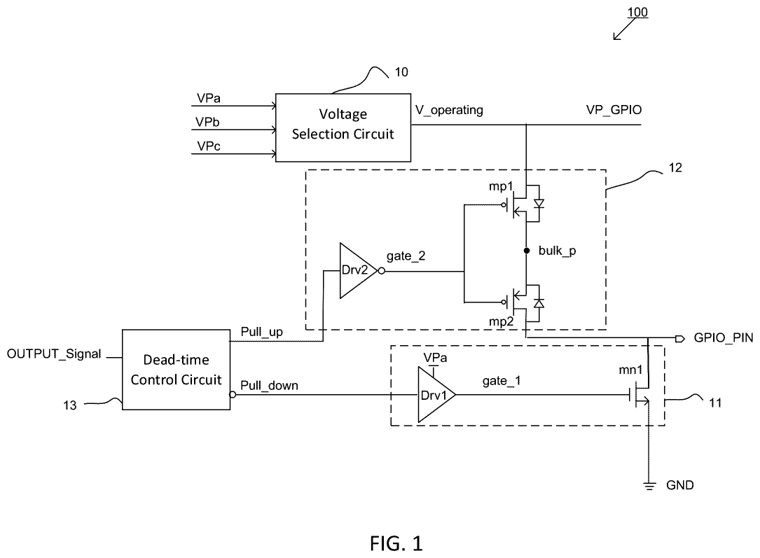

FIG. 1 is a schematic diagram of a GPIO circuit 100 according to an embodiment of the present disclosure. As shown in FIG. 1, there are multiple selectable power supply voltages with different magnitudes within a chip, for example, VPa, VPb, and VPc, where VPa>VPb>VPc. One of these power supply voltages is selected by a voltage selection circuit 10 as a working voltage V_operating to be provided to an operating voltage output terminal VP_GPIO. A first N-type Metal-Oxide-Semiconductor Field-Effect (hereinafter referred to as NMOS) transistor mn1 is coupled between a GPIO pin GPIO_PIN and a reference ground GND. The first NMOS transistor mn1 includes a drain coupled to the GPIO pin GPIO_PIN, a source coupled to the reference ground GND, and a gate coupled to a first gate drive circuit Drv1 to receive a first gate drive signal gate_1. A first P-type Metal-Oxide-Semiconductor Field-Effect (hereinafter referred to as PMOS) transistor mp1 and the second PMOS transistor mp2 are coupled in series between the operating voltage output terminal VP_GPIO and the GPIO pin GPIO_PIN. The first PMOS transistor mp1 includes a drain coupled to the operating voltage output terminal VP_GPIO, a gate and a source. The second PMOS transistor mp2 includes a drain coupled to the GPIO pin GPIO_PIN, a gate and a source. The source of the first PMOS transistor mp1, is connected to the source of the second PMOS transistor mp2, forming a first common node bulk_p. Both the gate of the first PMOS transistor mp1 and the gate of the second PMOS transistor mp2 are coupled to a second gate drive circuit Drv2 to receive a second gate drive signal gate_2. There are two body diodes in the equivalent circuit when the first PMOS transistor mp1 and the second PMOS transistor mp2 are coupled as shown in FIG. 1. When the first PMOS transistor mp1 and the second PMOS transistor mp2 are controlled by the second gate drive signal gate_2 to be turned ON simultaneously, the GPIO pin GPIO_PIN outputs the current voltage at the operating voltage output terminal VP_GPIO, while the first PMOS transistor mp1 and the second PMOS transistor mp2 are controlled by the second gate drive signal gate_2 to be turned OFF simultaneously, due to the presence of the two body diodes, the operating voltage output terminal VP_GPIO and the GPIO pin GPIO_PIN are effectively isolated from each other.

As shown in FIG. 1, in some embodiments of this disclosure, a pull-down circuit 11 of the GPIO circuit 100 includes the first NMOS transistor mn1 and the first gate drive circuit Drv1. A pull-up circuit 12 of the GPIO circuit 100 includes the first PMOS transistor mp1, the second PMOS transistor mp2, and the second gate drive circuit Drv2. In some embodiments, the maximum power supply voltage VPa among the multiple selectable power supply voltages within the chip is used to power the first gate drive circuit Drv1.

In some embodiments, the GPIO circuit 100 further includes a dead-time control circuit 13. The dead-time control circuit 13 receives the push-pull output control signal OUTPUT_signal and generates a pull-up signal Pull_up and a pull-down signal Pull_down based on the push-pull output control signal OUTPUT_signal. The pull-up signal Pull_up follows the same logic state as the push-pull output control signal OUTPUT_signal, while the pull-down signal Pull_down is inversed with respect to the push-pull output control signal OUTPUT_signal.

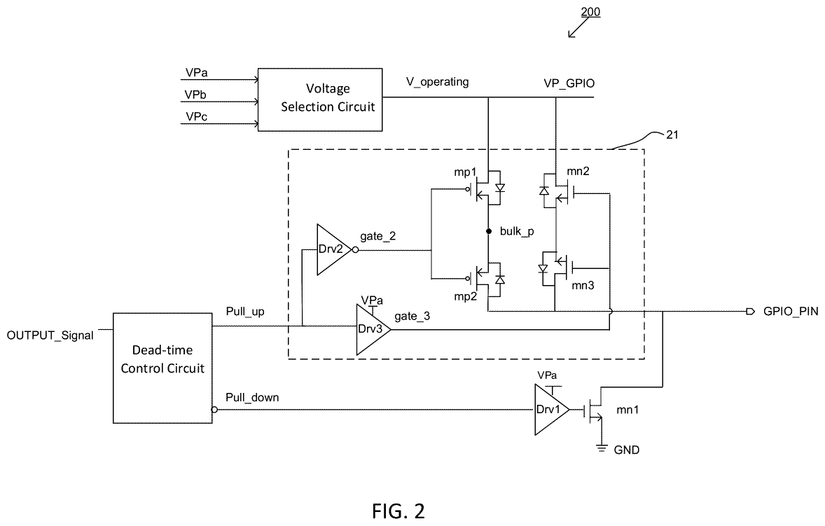

FIG. 2 is a schematic diagram of a GPIO circuit 200 according to an embodiment of the present disclosure. Compared to FIG. 1, the GPIO circuit 200 further includes a second NMOS transistor mn2 and a third NMOS transistor mn3 coupled in series between the operating voltage output terminal VP_GPIO and the GPIO pin GPIO_PIN. The second NMOS transistor mn2 includes a drain coupled to the operating voltage output terminal VP_GPIO, a gate and a source. The third NMOS transistor mn3 includes a drain coupled to the GPIO pin GPIO_PIN, a gate and a source. The source of the second NMOS transistor mn2 is coupled to the source of the third NMOS transistor mn3. The gates of both the second NMOS transistor mn2 and the third NMOS transistor mn3 are coupled to a third gate drive circuit Drv3 to receive a third gate drive signal gate_3. There are another two body diodes in the equivalent circuit when the second NMOS transistor mn2 and the third NMOS transistor mn3 are coupled as shown in FIG. 2.

As shown in FIG. 2, in some embodiments of this disclosure, a pull-up circuit 21 includes four transistors (mp1, mp2, mn2, mn3) related to a pull-up operation, the second gate drive circuit Drv2, and the third gate drive circuit Drv3. In some embodiments, the maximum power supply voltage VPa among the multiple selectable power supply voltages within the chip is used to power the third gate drive circuit Drv3.

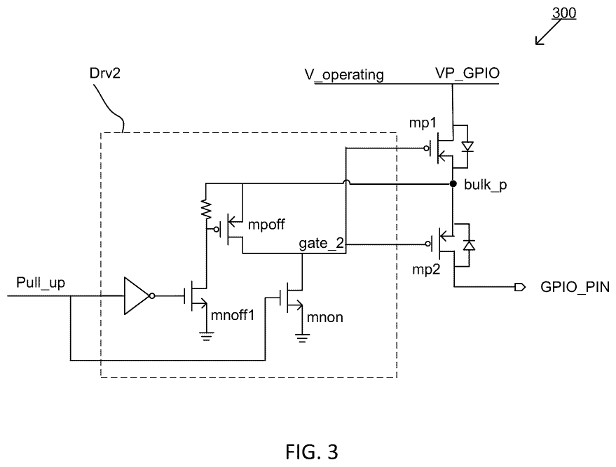

Referring to an exemplary pull-up circuit 300 of FIG. 3, in some embodiments of this disclosure, the second gate drive circuit Drv2 further includes a fourth NMOS transistor mnon. The fourth NMOS transistor includes a source coupled to a reference ground, a gate coupled to the pull-up signal Pull_up, and a drain coupled to the gates of the first PMOS transistor mp1 and the second PMOS transistor mp2 to provide the second gate drive signal gate_2. When the pull-up signal Pull_up is in the first logical state (e.g., logic high), the fourth NMOS transistor mnon is turned ON, then the gates of both the first PMOS transistor mp1 and the second PMOS transistor mp2 are grounded, thus the first PMOS transistor mp1 and the second PMOS transistor mp2 are turned ON simultaneously. At this time, the voltage at the GPIO pin GPIO_PIN is pulled up to the same potential as the operating voltage output terminal VP_GPIO.

The second gate drive circuit Drv2 may further includes a third PMOS transistor mpoff and a fifth NMOS transistor mnoff1. The third PMOS transistor mpoff includes a gate coupled to a drain of the fifth NMOS transistor mnoff1, a source coupled to the first common node bulk_p, and a drain coupled to the gates of both the first PMOS transistor mp1 and the second PMOS transistor mp2 to provide the second gate drive signal gate_2. The fifth NMOS transistor mnoff1 includes a drain, a source coupled to a reference ground and a gate coupled to the pull-up signal Pull_up through an inverter.

When the pull-up signal Pull_up is in the second logical state (e.g., logic low), the fifth NMOS transistor mnoff1 is turned ON, then the gate of the third PMOS transistor mpoff is grounded and the third PMOS transistor mpoff is turned ON, as a result, and the voltage at the gates of both the first PMOS transistor mp1 and the second PMOS transistor mp2 is pulled up to the same potential as the first common node bulk_p.

FIG. 3 only shows a part of the GPIO circuit according to the present disclosure, and more specifically, FIG. 3 illustrates an embodiment of the pull-up circuit 300. The second gate drive circuit Drv2 shown in FIG. 3 can also be implemented in the pull-up circuit 21 as shown in FIG. 2. No matter which power supply voltage (VA, VB or VC for example) is selected by the voltage selection circuit 10 as the working voltage V_operating, the second gate drive circuit Drv2 shown in FIG. 3 can ensure that the gates of the first PMOS transistor mp1 and the second PMOS transistor mp2 can be properly and reliably turned OFF, and also, the operating voltage output terminal VP_GPIO and the GPIO pin GPIO_PIN can be effectively isolated.

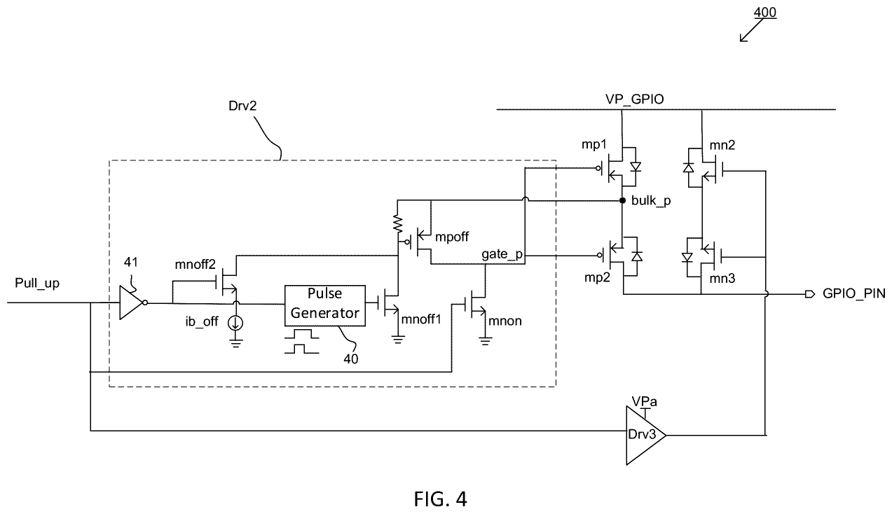

FIG. 4 illustrates a GPIO circuit 400 according to an embodiment of the present disclosure. Compared to FIG. 3, the second gate drive circuit Drv2 of the GPIO circuit 400 of FIG. 4 further includes a pulse generator 40, a sixth NMOS transistor mnoff2, and a first current source ib_off. The sixth NMOS transistor mnoff2 works in conjunction with the fifth NMOS transistor mnoff1. The sixth NMOS transistor mnoff2 includes a gate coupled to the pull-up signal Pull_up through an inverter 41, a source coupled to a reference ground through the first current source ib_off, and a drain coupled to the drain of the fifth NMOS transistor mnoff1. In these embodiments, the gate of the fifth NMOS transistor mnoff1 is coupled to the pull-up signal Pull_up sequentially through the pulse generator 40 and the inverter 41.

When the pull-up signal Pull_up flips from a first logical state (e.g., logic high) to a second logical state (e.g., logic low), the pulse generator 40 generates one pulse. The pulse activates the fifth NMOS transistor mnoff1 to be turned ON for the duration of the pulse. After the pulse ends, the third PMOS transistor mpoff is kept ON since the sixth NMOS transistor mnoff2 is kept ON for the rest of the time. As a result, the gate voltages of the first PMOS transistor mp1 and the second PMOS transistor mp2 are both continuously maintained at the same potential as the first common node bulk_p. A leakage current at the GPIO pin GPIO_PIN is thus determined by the magnitude of the first current source ib_off. Therefore, by using the second gate drive circuit Drv2 as shown in FIG. 4, the operating voltage output terminal VP_GPIO and the GPIO pin GPIO_PIN can be effectively isolated. Moreover, the magnitude of the leakage current at the GPIO pin GPIO_PIN can be effectively controlled. The second gate drive circuit Drv2 shown in FIG. 4 can also be implemented in the pull-up circuit 12 as shown in FIG. 1.

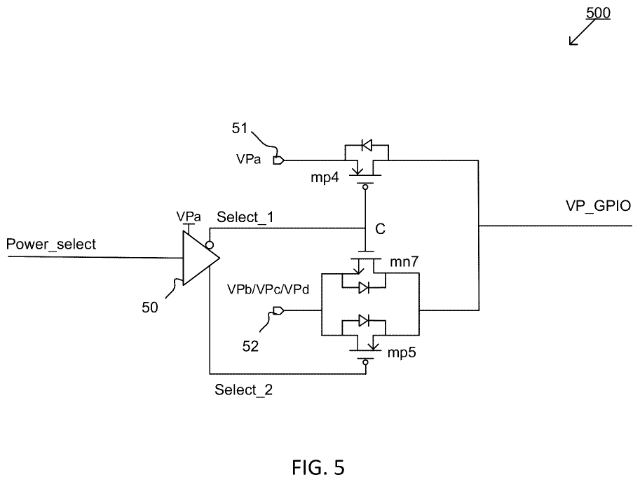

FIG. 5 provides an exemplary voltage selection circuit 500. The voltage selection circuit 500 may include a first amplification circuit 50, a seventh NMOS transistor mn7, a fourth PMOS transistor mp4, and a fifth PMOS transistor mp5. The fourth PMOS transistor mp4 includes a gate coupled to the first amplification circuit 50 to receive a first selection signal Select_1, a source coupled to a first power terminal 51, and drain coupled to the operating voltage output terminal VP_GPIO. The seventh NMOS transistor mn7 includes a gate coupled to the first amplification circuit 50 to receive the first selection signal Select_1, a source coupled to a second power terminal 52, and a drain coupled to the operating voltage output terminal VP_GPIO. The fifth PMOS transistor mp5 includes a gate coupled to the first amplification circuit 50 to receive a second selection signal Select_2, a source coupled to the operating voltage output terminal VP_GPIO, and drain coupled to the second power terminal 52.

The first power terminal 51 and the second power terminal 52 are coupled to different supply voltages within the chip. For example, in a power management chip that includes multiple buck circuits and multiple LDO circuits, various different power supply voltages including VPa, VPb, VPc and VPd may be assigned to the first power terminal 51 or the second power terminal 52. In one embodiment shown in FIG. 5, VPa, the maximum power supply voltage among the multiple selectable power supply voltages is assigned to the first power terminal 51, and the remaining multiple power supply voltages (e.g., VPb, VPc and VPd) are assigned to the second power terminal 52. The power supply voltages VPb, VPc and VPd have magnitudes that fall between zero and the maximum power supply voltage VPa.

The first amplification circuit 50 receives a voltage selection signal Power_select and provides the first selection signal Select_1 and the second selection signal Select_2 based on it. The first selection signal Select_1 is inversed with respect to the voltage selection signal Power_select, while the second selection signal Select_2 follows the same logic state as the voltage selection signal Power_select. In some embodiments, VPa, the maximum power supply voltage among the multiple selectable power supply voltages is used to power the first amplification circuit 50.

When the voltage selection signal Power_select is in a second logical state (e.g., logic low), the second selection signal Select_2 is also in the second logical state (e.g., logic low), driving both the seventh NMOS transistor mn7 and the fifth PMOS transistor mp5 to be turned ON. Since the gate-to-source voltages of the two transistors are different, there is a difference in their driving capabilities. For example, if the voltage at the second power terminal 52 now is very close to the maximum supply voltage VPa, then the fifth PMOS transistor mp5 may have a stronger driving capability which can ensure fast power supply. If the voltage at the second power terminal 52 now is very close to zero voltage, the seventh NMOS transistor mn7 has a stronger driving capability which can ensure fast power supply. Therefore, by using the exemplary voltage selection circuit 500, not only a selection of multiple selectable power supply voltages can be achieved, a fast power supply can also be guaranteed.

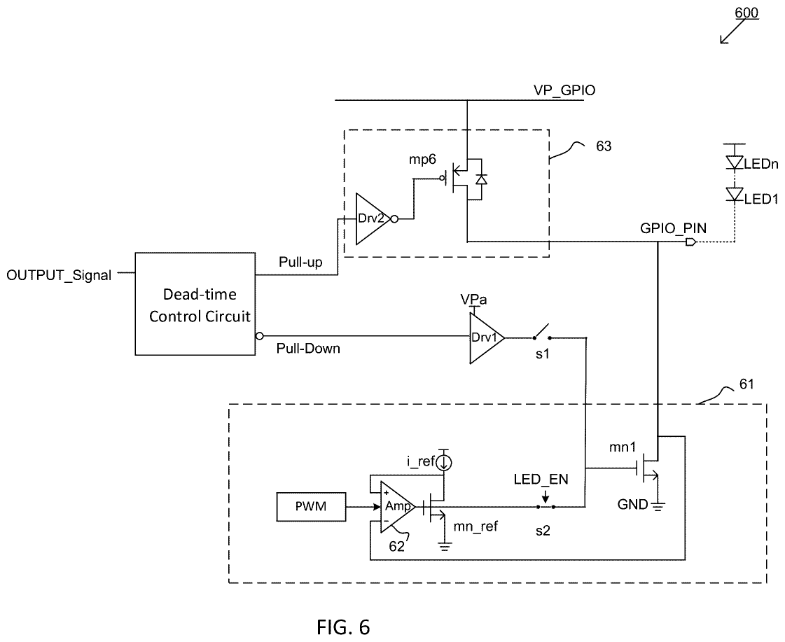

Referencing to FIG. 6, the present disclosure also provides a multifunctional GPIO circuit 600. This multifunctional GPIO circuit 600 includes a pull-up circuit and a pull-down circuit. The pull-down circuit includes a first NMOS transistor mn1 coupled between the GPIO pin GPIO_PIN and the reference ground GND, a first gate drive circuit Drv1 coupled to the gate of the first MOS transistor mn1, and a first switch s1. The first NMOS transistor mn1 includes a gate, source coupled to the reference ground GND, a drain coupled to the GPIO pin GPIO_PIN. The multifunctional GPIO circuit 600 further includes an LED drive circuit 61. The LED drive circuit 61 includes the first NMOS transistor mn1, an eighth NMOS transistor mn_ref, a second current source i_ref coupled to the drain of the eighth NMOS transistor mn_ref, a second amplification circuit 62 coupled to the gate of the first NMOS transistor mn1, and a second switch s2. The second amplification circuit 62 includes a first input terminal, a second input terminal, and an output terminal. Its first input terminal is coupled to the drain of the eighth NMOS transistor mn_ref, its second input terminal is coupled to the drain of the first NMOS transistor mn1, its output terminal is coupled both to the gate of the eighth NMOS transistor mn_ref and the gate of the first NMOS transistor mn1 through the second switch s2.

In the multifunctional GPIO circuit 600, the first NMOS transistor mn1 is a component of both the pull-down circuit and the LED drive circuit 61, in other words, the first NMOS transistor mn1 is reused by the two circuits. Based on specific application requirements, the multifunctional GPIO circuit 600 can be configured to operate in a LED drive mode flexibly, during which the GPIO pin GPIO_PIN is repurposed to drive an LED. When operating in the LED drive mode, the second switch s2 is configured to be turned ON by the LED enable signal LED_EN, the first switch s1 is configured to be turned OFF by the LED enable signal LED_EN, meanwhile, the pull-up circuit 63 is not operational. In one embodiment, the pull-up circuit 63 can be configured inoperative by turning off a switch (not shown) coupled to the pull-up circuit 63. In other embodiments, the pull-up circuit 63 can be configured inoperative by enabling an open-drain output mode of the GPIO circuit 600. The pull-up circuit 63 shown in FIG. 6 is merely an example of the multifunctional GPIO circuit 600. The multifunctional GPIO circuit 600 may include one or a combination of the pull-up circuit 12 shown in FIG. 1, the pull-up circuit 21 shown in FIG. 2, the pull-up circuit 300 shown in FIG. 3, and the pull-up circuit 400 shown in FIG. 4.

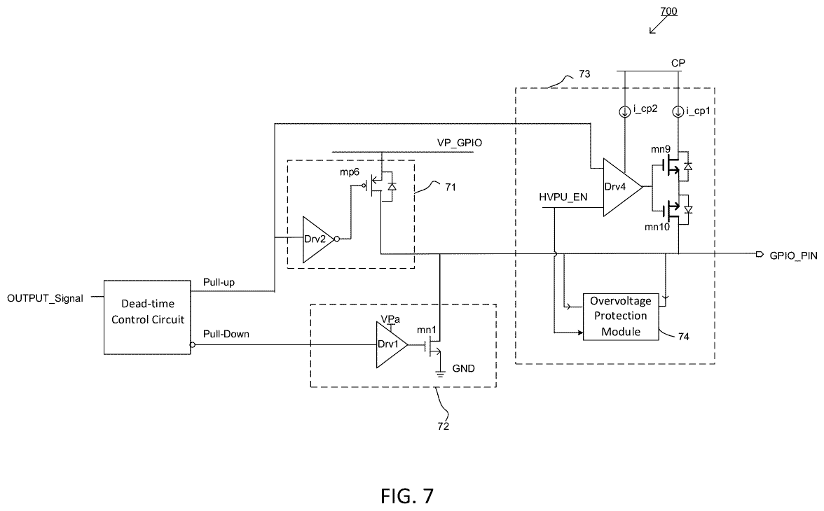

Referencing to FIG. 7, the present disclosure further provides another multifunctional GPIO circuit 700. The multifunctional GPIO 700 includes a pull-up circuit 71, a pull-down circuit 72, and a high-voltage pull-up circuit 73. Based on specific application requirements, the multifunctional GPIO circuit 700 can be configured to operate in push-pull mode or high-voltage pull-up current source output mode accordingly. When operating in the push-pull mode, the high-voltage pull-up circuit 73 is not operative, while the pull-up circuit 71 works in conjunction with the pull-down circuit 72. When operating in the high-voltage pull-up current source output mode, the pull-up circuit 71 is not operative, while the high-voltage pull-up circuit 73 works in conjunction with the pull-down circuit 72. That is to say, the pull-down circuit 72 is reused in both of these two modes. In one embodiment, the pull-up circuit 71 can be configured inoperative by closing a switch (not shown) coupled to the pull-up circuit 71. In other embodiments, the pull-up circuit 71 can be configured inoperative by enabling an open-drain output mode of the multifunctional GPIO 700.

The pull-up circuit 71 may include one or a combination of the pull-up circuit 12 shown in FIG. 1, the pull-up circuit 21 shown in FIG. 2, the pull-up circuit 300 shown in FIG. 3 and the pull-up circuit 400 shown in FIG. 4. The pull-down circuit 72 may include the pull-down circuits 11 shown in FIG. 1 or the pull-down circuit in FIG. 6. The high-voltage pull-up circuit 73 includes a ninth NMOS transistor mn9 and a tenth NMOS transistor mn10 coupled in series between a charge pump output terminal CP and the GPIO pin GPIO_PIN. The ninth NMOS transistor mn9 includes a gate, a source, and drain coupled to the charge pump output terminal CP through a third current source i_cp1. The tenth NMOS transistor mn10 includes a gate, a source, and a drain coupled to the GPIO pin GPIO_PIN. The source of the ninth NMOS transistor mn9 is coupled to the source of the tenth NMOS transistor mn10. The gates of both the ninth NMOS transistor mn9 and the tenth NMOS transistor mn10 are coupled to an output terminal of a fourth gate drive circuit Drv4. There are two body diodes in the equivalent circuit when the ninth NMOS transistor mn9 and the tenth NMOS transistor mn10 are coupled as shown in FIG. 7. When operating in the high-voltage pull-up current source output mode, the fourth gate drive circuit Drv4 is controlled by the high-voltage enable signal HVPU_EN to simultaneously turn ON the ninth NMOS transistor mn9 and the tenth NMOS transistor mn10 and the GPIO pin GPIO_PIN is used to provide current.

In some embodiments, the fourth gate drive circuit Drv4 includes a first input terminal configured to receive the pull-up signal Pull_up, a second input terminal configured to receive the high-voltage pull-up enable signal HVPU_EN, and an output terminal. In some embodiments, a fourth current source i_cp2, which is coupled to the charge pump output terminal CP, is used to supply power to the fourth gate drive circuit Drv4.

In some embodiments, the charge pump output terminal CP is coupled to a charge pump (not shown) within the chip. In some embodiments, the charge pump provides a high voltage, here “high voltage” refers to a voltage higher than the maximum supply voltage VPa, typically 5-18 volts, but it can also be set to greater than 18 volts. The ninth NMOS transistor mn9 and the tenth NMOS transistor mn10 may be high-voltage transistors (for example, LDMOS transistors). In some embodiments, the high-voltage pull-up circuit 73 also includes an overvoltage protection module 74, which receives the high-voltage pull-up enable signal HVPU_EN and the voltage at the GPIO pin GPIO_PIN. When the high-voltage pull-up enable signal HVPU_EN is in the first state (e.g., logic high), the overvoltage protection module 74 is activated to monitor the voltage at the GPIO pin GPIO_PIN. If the voltage at the GPIO pin GPIO_PIN exceeds a threshold, the overvoltage protection module 74 can provide a discharge current to stabilize the voltage at the GPIO pin GPIO_PIN within a preset range.

While some embodiments of the present invention have been described in detail above, it should be understood, of course, these embodiments are for exemplary illustration only and are not intended to limit the scope of the present invention. Various modifications are contemplated, and they obviously will be resorted to by those skilled in the art without departing from the spirit and the scope of the invention.

1. A general input/output (GPIO) circuit having an output circuit, the output circuit comprising:
a first n-type metal-oxide-semiconductor field-effect (NMOS) transistor, coupled between a GPIO pin and a reference ground;
a first p-type metal-oxide-semiconductor field-effect (PMOS) transistor and a second PMOS transistor, coupled in series between an operating voltage output terminal and the GPIO pin;
wherein the first NMOS transistor includes a source coupled to the reference ground, a drain coupled to the GPIO pin and a gate;
the first PMOS transistor includes a drain coupled to the operating voltage output terminal, a gate and a source;
the second PMOS transistor includes a drain coupled to the GPIO pin, a gate and a source;
and wherein the source of the first PMOS transistor is coupled to the source of the second PMOS transistor and forms a first common node.

2. The GPIO circuit as claimed in claim 1, wherein the gate of the first NMOS transistor is coupled to a first gate drive circuit, and a maximum power supply voltage among multiple selectable power supply voltages within a chip is used to power the first gate drive circuit.

3. The GPIO circuit as claimed in claim 1, the output circuit further includes a second NMOS transistor and a third NMOS transistor coupled in series between the operating voltage output terminal and the GPIO pin; wherein the second NMOS transistor includes a drain coupled to the operating voltage output terminal, a gate and a source; the third NMOS transistor includes a drain coupled to the GPIO pin, a gate and a source; and wherein the source of the second NMOS transistor is coupled to the source of the third NMOS transistor, and the gates of both the second NMOS transistor and the third NMOS transistor are coupled to a third gate drive circuit.

4. The GPIO circuit as claimed in claim 3, wherein the maximum power supply voltage among the multiple power supply voltages within the chip is used to power the third gate drive circuit.

5. The GPIO circuit as claimed in claim 1, the gates of the first PMOS transistor and the second PMOS transistor are both coupled to a second gate drive circuit, which drives the first PMOS transistor and the second PMOS transistor to be tuned ON simultaneously or to be turned OFF simultaneously; when both the first PMOS transistor and the second PMOS transistor are turned OFF simultaneously, the gate voltage of the first PMOS transistor and the gate voltage of the second PMOS transistor are configured to be the same as the voltage of the first common node.

6. The GPIO circuit as claimed in claim 1, the gates of the first PMOS transistor and the second PMOS transistor are both coupled to a second gate drive circuit, which includes a fourth NMOS transistor, a third PMOS transistor, and a fifth NMOS transistor;
wherein the fourth NMOS transistor includes a gate configured to receive a pull-up signal, a source coupled to a reference ground, and a drain coupled to the gates of both the first PMOS transistor and the second PMOS transistor;
the third PMOS transistor includes a gate coupled to the drain of the fifth NMOS transistor, a source coupled to the source of the first PMOS transistor, and a drain coupled to the gates of both the first PMOS transistor and the second PMOS transistor;
the fifth NMOS transistor includes a gate configured to receive an inverted pull-up signal, a source coupled to a reference ground, and a drain coupled to the gate of the third PMOS transistor.

7. The GPIO circuit as claimed in claim 1, the gates of the first PMOS transistor and the second PMOS transistor are both coupled to a second gate drive circuit, the second gate drive circuit includes a fourth NMOS transistor, a third PMOS transistor, a fifth NMOS transistor, a sixth NMOS transistor, a pulse generator, and a first current source;
wherein the fourth NMOS transistor includes a gate coupled to a pull-up signal, a source coupled to a reference ground, and drain coupled to the gates of both the first PMOS transistor and the second PMOS transistor;
the third PMOS transistor includes a gate coupled to the drain of the fifth NMOS transistor, a source coupled to the source of the first PMOS transistor, and a drain coupled to the gates of both the first PMOS transistor and the second PMOS transistor, its, and its gate;
the fifth NMOS transistor includes a gate coupled to the pulse generator, a source coupled to a reference ground, and a drain coupled to the gate of the third PMOS transistor;
the sixth NMOS transistor includes a gate configured to receive an inverted pull-up signal, source coupled to a reference grounded through the first current source, and a drain coupled to the drain of the fifth NMOS transistor;
and wherein the pulse generator receives the inverted pull-up signal and generates a single pulse based on the inverted pull-up signal.

8. The GPIO circuit as claimed in claim 1 further includes a voltage selection circuit, the voltage selection circuit includes a seventh NMOS transistor, a fourth PMOS transistor, a fifth PMOS transistor, and a first amplifier circuit;
wherein the first amplifier circuit receives a voltage selection signal and provides a first selection signal and a second selection signal based on the voltage selection signal;
the fourth PMOS transistor includes a gate coupled to the first selection signal, a source coupled to a first power terminal, and a drain coupled to the operating voltage output terminal;
the seventh NMOS transistor includes a gate coupled to the first selection signal, a source coupled to a second power terminal, and a drain coupled to the operating voltage output terminal;
the fifth PMOS transistor includes a gate coupled to the second selection signal, a source coupled to the operating voltage output terminal, and a drain coupled to the second power terminal.

9. The GPIO circuit as claimed in claim 8, wherein the first selection signal is inversed with respect to the voltage selection signal, and the second selection signal follows the same logic state as the voltage selection signal.

10. The GPIO circuit as claimed in claim 8, wherein the maximum power supply voltage among the multiple power supply voltages within the chip is used to power to the first amplifier circuit.

11. The GPIO circuit as claimed in claim 8, wherein the maximum power supply voltage among the multiple power supply voltages within the chip is assigned to the first power terminal, and the remaining power supply voltages are assigned to the second power terminal.

12. A GPIO circuit having an output circuit, the output circuit comprising:
a first n-type metal-oxide-semiconductor field-effect (NMOS) transistor, coupled between a GPIO pin and a reference ground; wherein the first NMOS transistor is reused by a pull-down circuit of the output circuit and a LED driving circuit.

13. The GPIO circuit as claimed in claim 12, wherein the GPIO circuit includes an LED drive mode, in the LED drive mode, a pull-up circuit of the GPIO circuit is configured inoperative.

14. The GPIO circuit as claimed in claim 12, wherein the output circuit comprising:
a first n-type metal-oxide-semiconductor field-effect (NMOS) transistor, coupled between a GPIO pin and a reference ground;
a first gate drive circuit, a first switch, a second amplifier circuit, and a second switch which are coupled to a gate of the first NMOS transistor;
an eighth NMOS transistor and a second current source coupled to a drain of the eighth NMOS transistor;
wherein the second amplifier circuit includes a first input terminal coupled to the drain of the eighth NMOS transistor, a second input terminal coupled to a drain of the first NMOS transistor, and an output terminal coupled to the gate of the first NMOS transistor through the second switch and a gate of the eighth NMOS transistor; and wherein
a source of the eighth NMOS transistor and a source of the first NMOS transistor are both coupled to a reference ground.

15. A GPIO circuit having an output circuit, the output circuit includes a pull-up circuit, a pull-down circuit, and a high-voltage pull-up circuit.

16. The GPIO circuit as claimed in claim 15, wherein the GPIO circuit includes a high-voltage pull-up current source output mode, in the high-voltage pull-up current source output mode, a pull-up circuit of the GPIO circuit is configured inoperative, a high-voltage pull-up circuit of the GPIO circuit is configured to work in conjunction with a pull-down circuit of the GPIO circuit.

17. The GPIO circuit as claimed in claim 15, wherein the output circuit comprising:
a first n-type metal-oxide-semiconductor field-effect (NMOS) transistor, coupled between a GPIO pin and a reference ground;
a ninth NMOS transistor and a tenth NMOS transistor, coupled in series between a charge pump output terminal and the GPIO pin;
wherein the ninth NMOS transistor includes a drain coupled to the charge pump output terminal through a third current source, a gate and a source;
the tenth NMOS transistor includes a drain coupled to the GPIO pin, a gate and a source;
the source of the ninth NMOS transistor is coupled to the source of the tenth NMOS transistor;
and wherein the gate of the ninth NMOS transistor and the gate of the tenth NMOS transistor are coupled to a fourth gate drive circuit.

18. The GPIO circuit as claimed in claim 17, wherein the fourth gate drive circuit includes a first input terminal configured to receive a pull-up signal, a second input terminal configured to receive a high-voltage pull-up enable signal, and an output terminal.
